(19) United States
(12) Patent Application Publication
(10) Pub. No.: US 2019/0386090 A1
(43) Pub. Date: Dec. 19, 2019

(54) DISPLAY SCREEN

(71) Applicant: Wuhan China Star Optoelectronics Technology Co., Ltd., Wuhan, Hubei (CN)

(72) Inventors: Caiqin CHEN, Wuhan, Hubei (CN); Yu ZHAO, Wuhan, Hubei (CN)

(73) Assignee: WUHAN CHINA STAR OPTOELECTRONICS TECHNOLOGY CO., LTD., Wuhan, Hubei (CN)

(21) Appl. No.: 15/550,482

(22) PCT Filed: Jul. 6, 2017
(86) PCT No.: PCT/CN2017/092003

§ 371 Date: Aug. 11, 2017

(30) Foreign Application Priority Data
Jun. 6, 2017 (CN) 201710417287.1

(51) Int. Cl. H01L 27/32; H01L 51/52

(52) U.S. Cl. CPC H01L 27/3297; H01L 51/5206; H01L 51/5225

(57) ABSTRACT

The technical field of display device is related to. A display screen is disclosed. The display screen includes an integrated circuit board and an organic insulating film. A power signal line is arranged on the integrated circuit board. The organic insulating film is provided with a plurality of grooves with an equal distance thereamong, and a cathode is arranged on the organic insulating film. The cathode is buried in a groove and contacts the power signal line, or an anode is arranged on the cathode, is buried in the groove, and contacts the power signal line. The organic insulating film near an interface between the anode and the cathode is flat, and a disconnection would not occur to the cathode that is formed under the anode. Therefore, a signal of the integrated circuit board can be transmitted to the cathode in the active area, and display defect of the panel will not be resulted in. A width of the anode is reduced, and the anode is buried in the groove. That is, the anode is disconnected from an edge of the organic insulating film. In this manner, the case in the prior art, i.e., the organic insulating film near the interface between the anode and the cathode becomes non-flat after developing of an organic barrier layer, and an under cut is formed at an edge of the anode, which leads to disconnection of the cathode, can be avoided.

### CROSS REFERENCE TO RELATED APPLICATIONS

The present application claims the priority of Chinese patent application CN201710417287.1, entitled “Display Screen” and filed on Jun. 6, 2017, the entirety of which is incorporated herein by reference.

### FIELD OF THE INVENTION

The present disclosure relates to the technical field of display device, and particularly to a display screen.

### BACKGROUND OF THE INVENTION

Flexible Organic Light-Emitting Diode (OLED) display screen is a new kind of display device in which Thin Film Transistors (TFTs) and OLEDs are manufactured on a flexible and bendable substrate. At present, most of the commonly seen small sized OLED display screens have a top light-emitting structure. In this kind of display screens, a cathode in an active area is totally covered, and an organic barrier layer near an interface between the cathode and an anode should be flat. However, due to influence of developing of the organic barrier layer, a disconnection would occur to the cathode under the anode. As a result, a signal of an integrated circuit board cannot be transmitted to the anode in the active area, and display defect of the panel would be brought about.

### SUMMARY OF THE INVENTION

With respect to the technical defect in the prior art, the present disclosure provides a display screen.

In order to achieve the above purpose, the present disclosure provides a display screen, which comprises an integrated circuit board and an organic insulating film. A power signal line is arranged on the integrated circuit board. The organic insulating film is provided with a plurality of grooves with an equal distance thereamong, and a cathode is arranged on the organic insulating film. The cathode is buried in a groove and contacts the power signal line, or an anode is arranged on the cathode, is buried in the groove, and contacts the power signal line.

In the aforesaid display screen, the cathode is made of Mg or Al.

In the aforesaid display screen, a thickness of the cathode is in a range from 800 Å to 1200 Å.

In the aforesaid display screen, the thickness of the cathode is 1000 Å.

In the aforesaid display screen, the organic insulating film is flat.

The display screen further comprises a TFT that is connected with the integrated circuit board.

The display screen further comprises an OLED that is connected with the integrated circuit board.

In the aforesaid display screen, the anode is disconnected from an edge of the organic insulating film.

Compared with the prior art, in the display screen provided herein, through following arrangements, i.e., the integrated circuit board being provided with the power signal line, the organic insulating film being provided with a plurality of grooves with an equal distance thereamong, a cathode being arranged on the organic insulating film, and the cathode being buried in a groove and contacting the power signal line, the organic insulating film near an interface between the anode and the cathode is flat, and a disconnection would not occur to the cathode that is formed under the anode. Therefore, a signal of the integrated circuit board can be transmitted to the cathode in the active area, and display defect of the panel will not be resulted in. Alternatively, an anode is arranged on the cathode, is buried in the groove, and contacts the power signal line. A width of the anode is reduced, and the anode is buried in the groove. That is, the anode is disconnected from an edge of the organic insulating film. In this manner, the case in the prior art, i.e., the organic insulating film near the interface between the anode and the cathode becomes non-flat after developing of an organic barrier layer, and an under cut is formed at an edge of the anode, which leads to disconnection of the cathode, can be avoided.

The above technical features can be combined in any suitable manner, or substituted by the equivalent technical features, as long as the purpose of the present disclosure can be achieved.

### BRIEF DESCRIPTION OF THE DRAWINGS

The present disclosure will be illustrated in detail hereinafter with reference to the embodiments and the accompanying drawings. In the drawings:

FIG. 1 is a sectional view of a display screen according to one embodiment of the present disclosure;

FIG. 2 is a top view of a display screen according to one embodiment of the present disclosure; and

FIG. 3 is a sectional view of a display screen according to the other embodiment of the present disclosure.

In the drawings, the same components are represented by the same reference signs, and the size of each component does not represent the actual size of the corresponding component.

### DETAILED DESCRIPTION OF THE EMBODIMENTS

The present disclosure will be further explained hereinafter with reference to the accompanying drawings.

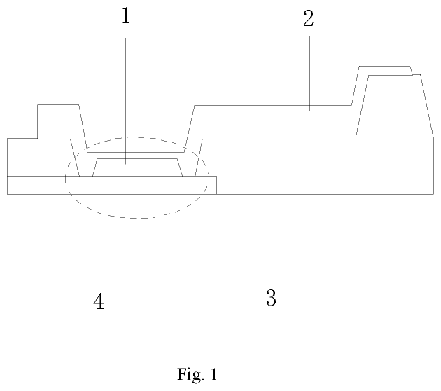

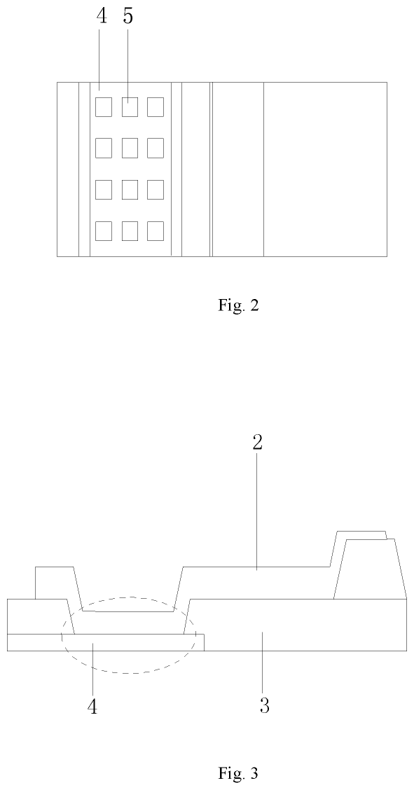

As shown in FIGS. 1 and 2, a display screen comprises an integrated circuit board and an organic insulating film 3. A power signal line 4 is arranged on the integrated circuit board. The organic insulating film 3 is provided with a plurality of grooves 5 (as shown in FIG. 2) with an equal distance thereamong, and a cathode 2 is arranged on the organic insulating film 3. The cathode 2 is buried in a groove 5 and contacts the power signal line 4. The organic insulating film 3 near an interface between an anode 1 and the cathode 2 is flat, and a disconnection would not occur to the cathode 2 that is formed under the anode 1. Therefore, a signal of the integrated circuit board can be transmitted to the cathode 2 in the active area, and display defect of the panel will not be resulted in.

According to one embodiment, as shown in FIG. 3, an anode 1 is arranged on the cathode 2, is buried in the groove 5, and contacts the power signal line 4. In the prior art, the organic insulating film 3 is provided with via holes. Here, the via holes are replaced by grooves 5 which have a larger area. A width of the anode 1 is reduced, and the anode 1 is buried in the groove 5. That is, the anode 1 is disconnected from an edge of the organic insulating film 3. In this manner, the case in the prior art, i.e., the organic insulating film 3 near the interface between the anode 1 and the cathode 2 becomes non-flat after developing of an organic barrier layer, and an under cut is formed at an edge of the anode 1, which leads to disconnection of the cathode 2, can be avoided.

According to one preferred embodiment, a wiring of the cathode 2 is made of Mg or Al.

According to one embodiment, a thickness of the wiring of the cathode 2 is in a range from 800 Å to 1200 Å, and thus a light transmittance thereof can be ensured.

According to one preferred embodiment, the thickness of the wiring of the cathode 2 is 1000 Å. Since the thickness of the cathode 2 is small and the cathode 2 in an active area is totally covered, the cathode 2 is connected to an electric potential wiring through the anode 1 which passes through the groove in the organic insulating film 3, and then connected to the integrated circuit board.

According to one embodiment, the organic insulating film 3 near the interface between the anode 1 and the cathode 2 is flat. The organic insulating film 3 will not be affected by the developing of the transparent organic barrier layer. The disconnection will not easily occur to the cathode 2 under the anode 1, and disconnection will not easily occur to the cathode 2 on an upper edge, a right edge, and a left edge. A signal of the integrated circuit board can be transmitted to the cathode 2 in the active area, the cathode 2 will not be curved, and a good display effect can be obtained.

According to one embodiment, the display screen further comprises a TFT that is connected with the integrated circuit board.

According to one embodiment, the display screen further comprises an OLED that is connected with the integrated circuit board.

According to one embodiment, the anode 1 is disconnected from an edge of the organic insulating film 3.

According to one embodiment, the organic insulating film 3 is provided with grooves 5 with larger areas to replace via holes arranged therein in the prior art. A width of the anode 1 is reduced, and the anode 1 is buried in the groove 5 of the organic insulating film 3. That is, the anode 1 is disconnected from an edge of the organic insulating film 3. In this manner, the case in the prior art, i.e., the organic insulating film 3 near the interface between the anode 1 and the cathode 2 becomes non-flat after developing of a transparent organic barrier layer, and a depression is formed at an edge of the anode 1, which leads to disconnection of the cathode 2, can be avoided. A bridge anode 1 between the cathode 2 and the anode 1 is removed, so that the cathode 2 directly contacts the anode 1 (a contact impedance thereof is increased slightly).

The present disclosure is illustrated in detail in combination with preferred embodiments hereinabove, but it can be understood that the embodiments disclosed herein can be improved or substituted without departing from the protection scope of the present disclosure. In particular, as long as there are no structural conflicts, the technical features disclosed in each and every embodiment of the present disclosure can be combined with one another in any way, and the combined features formed thereby are within the protection scope of the present disclosure. The present disclosure is not limited by the specific embodiments disclosed herein, but includes all technical solutions falling into the protection scope of the claims.

1. A display screen, comprising an integrated circuit board and an organic insulating film,
wherein a power signal line is arranged on the integrated circuit board;
wherein the organic insulating film is provided with a plurality of grooves with an equal distance thereamong, and a cathode is arranged on the organic insulating film; and
wherein the cathode is buried in a groove and contacts the power signal line, or an anode is arranged on the cathode, is buried in the groove, and contacts the power signal line.

2. The display screen according to claim 1, further comprising a TFT that is connected with the integrated circuit board.

3. The display screen according to claim 2, further comprising an OLED that is connected with the integrated circuit board.

4. The display screen according to claim 3, wherein the cathode is made of Mg or Al.

5. The display screen according to claim 4, wherein the organic insulating film is flat.

6. The display screen according to claim 5, wherein the anode is disconnected from an edge of the organic insulating film.

7. The display screen according to claim 1, wherein the cathode is made of Mg or Al.

8. The display screen according to claim 7, wherein a thickness of the cathode is in a range from 800 Å to 1200 Å.

9. The display screen according to claim 8, wherein the thickness of the cathode is 1000 Å.

10. The display screen according to claim 9, further comprising a TFT that is connected with the integrated circuit board.

11. The display screen according to claim 9, further comprising an OLED that is connected with the integrated circuit board.

12. The display screen according to claim 1, wherein the organic insulating film is flat.

13. The display screen according to claim 1, wherein the anode is disconnected from an edge of the organic insulating film.

14. The display screen according to claim 1, further comprising an OLED that is connected with the integrated circuit board.
